(19) United States
(12) Patent Application Publication
(10) Pub. No.: US 2025/0089352 A1
(43) Pub. Date: Mar. 13, 2025

(54) SEMICONDUCTOR DEVICE

(71) Applicant: Samsung Electronics Co., Ltd., Suwon-si (KR)

(72) Inventors: Chang Woo Noh, Suwon-si (KR); Myung Gil Kang, Suwon-si (KR); Byeong Hee Son, Suwon-si (KR)

(21) Appl. No.: 18/434,041

(22) Filed: Feb. 6, 2024

(30) Foreign Application Priority Data
Sep. 11, 2023 (KR) 10-2023-0120444

(51) Int. Cl. H01L 27/088; H01L 21/8234; H01L 29/06; H01L 29/417; H01L 29/423; H01L 29/45; H01L 29/66; H01L 29/775

(52) U.S. Cl. CPC H10D 84/83; H10D 30/014; H10D 30/43; H10D 30/6729; H10D 30/6735; H10D 62/121; H10D 64/017; H10D 64/62; H10D 84/0128; H10D 84/013; H10D 84/0149; H10D 84/0151; H10D 84/038

(57) ABSTRACT

A semiconductor includes a substrate, first and second active patterns that are on the substrate and extend in a first horizontal direction, a first gate electrode that is on the first active pattern and extends in a second horizontal direction, a second gate electrode that is on the second active pattern and extends in the second horizontal direction, an active cut trench that extends in the second horizontal direction and is between the first gate electrode and the second gate electrode, an active cut including a first layer and a second layer on the first layer, a first source/drain region that is between the first gate electrode and the active cut and is on the first active pattern, and a first source/drain contact that is on the first source/drain region, where at least a part of the first source/drain contact overlaps the first layer in a vertical direction.

### CROSS-REFERENCE TO RELATED APPLICATION

This application claims priority from Korean Patent Application No. 10-2023-0120444 filed on Sep. 11, 2023 in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device. Specifically, the present disclosure relates to a method for fabricating a semiconductor device including a MBCFET™ (Multi-Bridge Channel Field Effect Transistor).

### BACKGROUND

In one example scaling technology for increasing the density of a semiconductor device, a multi gate transistor in which a silicon body having a fin or nanowire shape is formed on a substrate and a gate is formed on a surface of the silicon body has been proposed.

Since such a multi gate transistor utilizes a three-dimensional channel, scaling is easily performed. Further, even if a gate length of the multi gate transistor is not increased, the current control capability may be improved. Furthermore, a SCE (short channel effect) in which potential of a channel region is influenced by a drain voltage may be effectively suppressed.

### SUMMARY

Aspects of the present disclosure provide a semiconductor device in which electrical characteristics are improved by forming a width of a source/drain contact to be relatively large.

According to some embodiments of the present disclosure, there is provided a semiconductor device, comprising a substrate, first and second active patterns that are on the substrate and extend in a first horizontal direction, where the second active pattern is spaced apart from the first active pattern in the first horizontal direction, a first gate electrode that is on the first active pattern and extends in a second horizontal direction that is different from the first horizontal direction, a second gate electrode that is on the second active pattern and extends in the second horizontal direction, where the second gate electrode is spaced apart from the first gate electrode in the first horizontal direction, an active cut trench that extends in the second horizontal direction and is between the first gate electrode and the second gate electrode, where the active cut trench separates the first and second active patterns, an active cut including a first layer and a second layer on the first layer, where the first layer is on a side wall and a bottom surface of the active cut trench, a first source/drain region that is between the first gate electrode and the active cut and is on the first active pattern, and a first source/drain contact that is on and electrically connected to the first source/drain region, where at least a part of the first source/drain contact overlaps the first layer in a vertical direction.

According to some embodiments of the present disclosure, there is provided a semiconductor device, comprising a substrate, a first active pattern that is on the substrate and extends in a first horizontal direction on the substrate, a gate electrode that is on the first active pattern and extends in a second horizontal direction that is different from the first horizontal direction, an active cut that is spaced apart from the gate electrode in the first horizontal direction, where the active cut extends in the second horizontal direction, where the active cut contacts a side wall of the first active pattern, and where the active cut includes a first layer that defines a side wall and a bottom surface of the active cut and a second layer on the first layer, a source/drain region that is between the gate electrode and the active cut and is on the first active pattern, where the source/drain region contacts the first layer, and a source/drain contact that is on and electrically connected to the source/drain region, where at least a part of a lower surface of the source/drain contact contacts an upper surface of the first layer, and where an upper surface of the source/drain contact and an upper surface of the second layer are coplanar.

According to some embodiments of the present disclosure, there is provided a semiconductor device, comprising a substrate, first and second active patterns that are on the substrate and extend in a first horizontal direction, where the second active pattern is spaced apart from the first active pattern in the first horizontal direction, a first plurality of nanosheets that are on the first active pattern and spaced apart from each other in a vertical direction, a second plurality of nanosheets that are on the second active pattern and spaced apart from each other in the vertical direction, a first gate electrode that is on the first active pattern and extends in a second horizontal direction that is different from the first horizontal direction, where the first gate electrode at least partially surrounds the first plurality of nanosheets, a second gate electrode that is on the second active pattern and extends in the second horizontal direction, where the second gate electrode is spaced apart from the first gate electrode in the first horizontal direction, and where the second gate electrode at least partially surrounds the second plurality of nanosheets, an active cut trench that extends in the second horizontal direction and is between the first gate electrode and the second gate electrode, where the active cut trench separates the first and second active patterns, an active cut including a first layer that is on a side wall and a bottom surface of the active cut trench, where the active cut includes a second layer that is on the first layer, where the first layer contacts side walls of each of the first and second active patterns, and where the first layer and the second layer include different materials from each other, a first source/drain region that is between the first gate electrode and the active cut and is on the first active pattern, where the first source/drain region contacts the first layer, a second source/drain region that is between the active cut and the second gate electrode and is on the second active pattern, where the second source/drain region contacts the first layer, a first source/drain contact that is on and electrically connected to the first source/drain region, where at least a part of a lower surface of the first source/drain contact contacts the first layer, and where a side wall of the first source/drain contact contacts the second layer, and a second source/drain contact disposed that is on and electrically connected to the second source/drain region, where at least a part of a lower surface of the second source/drain contact contacts the first layer, and where a side wall of the second source/drain contact contacts the second layer.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram describing a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIGS. 4, 5, 6, 7, 8, 9, 10, 11, 12, 13, 14, 15, 16, and 17 are intermediate process diagrams describing a method for fabricating a semiconductor device according to some embodiments of the present disclosure;

FIG. 18 is a cross-sectional view describing a semiconductor device according to some other embodiments of the present disclosure;

FIG. 19 is a cross-sectional view describing a semiconductor device according to still other embodiments of the present disclosure;

FIG. 20 is a cross-sectional view describing a semiconductor device according to still other embodiments of the present disclosure;

FIG. 21 is a cross-sectional view describing a semiconductor device according to still other embodiments of the present disclosure; and

FIGS. 22 and 23 are cross-sectional views describing a semiconductor device according to still other embodiments of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Although drawings of a semiconductor device according to some embodiments explain that the semiconductor device includes a transistor (MBCFET™ (Multi-Bridge Channel Field Effect Transistor) including a nanosheet or a fin type transistor (FinFET) including a channel region of a fin type pattern shape, the present disclosure is not limited thereto. In some other embodiments, the semiconductor device may, of course, include a tunneling transistor (tunneling FET) or a three-dimensional (3D) transistor. The semiconductor device according to some other embodiments may, of course, include a bipolar junction transistor, a laterally diffused metal oxide semiconductor (LDMOS), or the like.

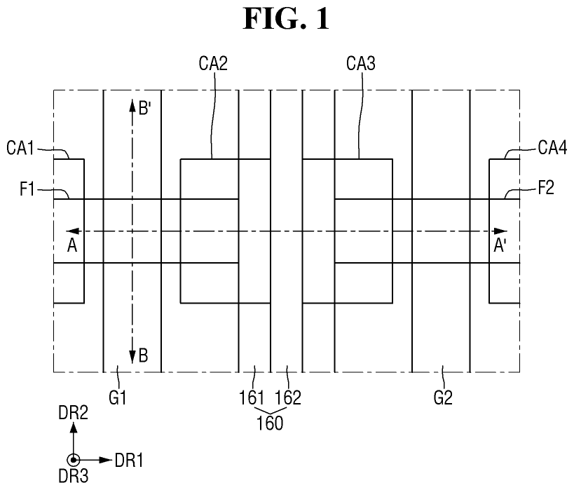

Hereinafter, the semiconductor device according to some embodiments of the present disclosure will be described with reference to FIGS. 1 to 3.

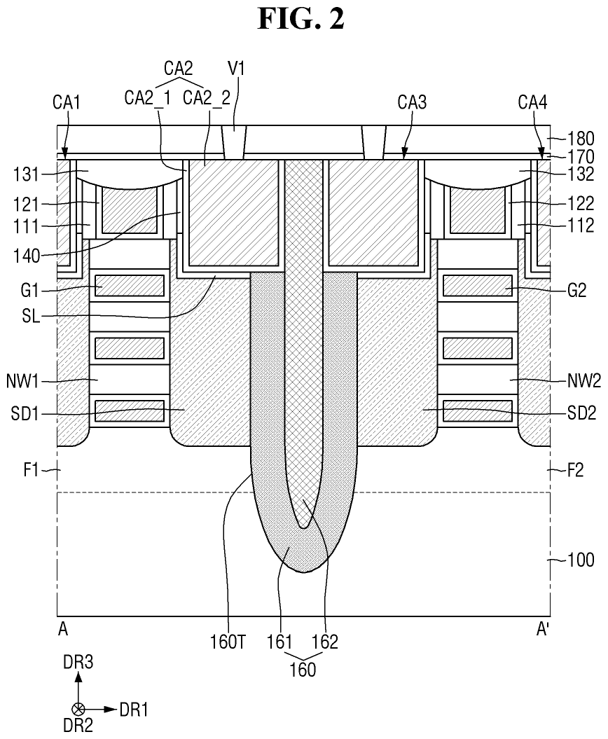

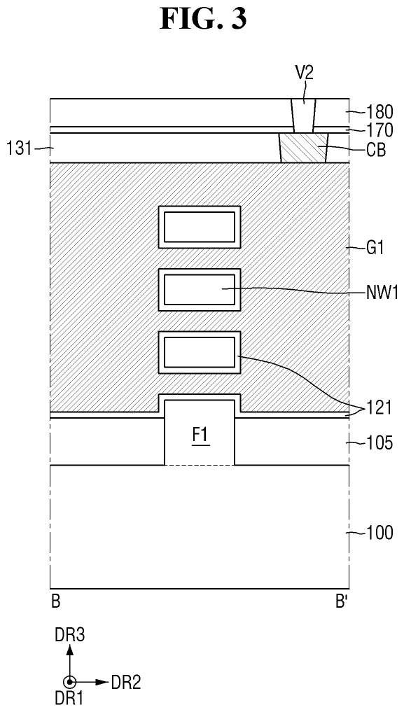

FIG. 1 is a layout diagram describing the semiconductor device according to some embodiments of the present disclosure. FIG. 2 is a cross-sectional view taken along line A-A′ of FIG. 1. FIG. 3 is a cross-sectional view taken along line B-B′ of FIG. 1.

Referring to FIGS. 1 to 3, the semiconductor device according to some embodiments of the present disclosure includes a substrate 100, first and second active patterns F1 and F2, a field insulating layer 105, a first and second plurality of nanosheets NW1 and NW2, first and second gate electrodes G1 and G2, first and second gate spacers 111 and 112, first and second gate insulating layers 121 and 122, first and second capping patterns 131 and 132, first and second source/drain regions SD1 and SD2, a first etching stop layer 140, first to fourth source/drain contacts CA1, CA2, CA3 and CA4, a silicide layer SL, a gate contact CB, an active cut 160, a second etching stop layer 170, a second interlayer insulating layer 180, and first and second vias V1 and V2.

The substrate 100 may be a silicon substrate or silicon-on-insulator (SOI). In some embodiments, the substrate 100 may include silicon germanium, silicon germanium on insulator (SGOI), indium antimonide, lead telluride, indium arsenide, indium phosphide, gallium arsenide, or gallium antimonide, but the present disclosure is not limited thereto.

Hereinafter, each of a first horizontal direction DR1 and a second horizontal direction DR2 may be defined as a direction parallel to an upper face of the substrate 100. The second horizontal direction DR2 may be defined as a direction different from the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the substrate 100.

The first active pattern F1 may extend in the first horizontal direction DR1 on the substrate 100. The second active pattern F2 may extend in the first horizontal direction DR1 on the substrate 100. The second active pattern F2 may be spaced apart from the first active pattern F1 in the first horizontal direction DR1. Each of the first active pattern F1 and the second active pattern F2 may protrude from the upper surface of the substrate 100 in the vertical direction DR3. For example, each of the first active pattern F1 and the second active pattern F2 may be a part of the substrate 100, and may include an epitaxial layer grown from the substrate 100.

The field insulating layer 105 may be disposed on the upper surface of the substrate 100. The field insulating layer 105 may at least partially surround side walls of each of the first active pattern F1 and the second active pattern F2. For example, the upper surface of each of the first active pattern F1 and the second active pattern F2 may protrude or extend beyond the upper surface of the field insulating layer 105 in the vertical direction DR3. However, the present disclosure is not limited thereto. In some other embodiments, the upper surfaces of each of the first active pattern F1 and the second active pattern F2 may be formed on the same plane (i.e., coplanar) as the upper surface of the field insulating layer 105. The field insulating layer 105 may include, for example, an oxide film, a nitride film, an oxynitride film or a combined film thereof.

A first plurality of nanosheets NW1 may be disposed on the first active pattern F1. The first plurality of nanosheets NW1 are disposed at an intersection between the first active pattern F1 and the first gate electrode G1. The first plurality of nanosheets NW1 may include a plurality of nanosheets stacked on the first active pattern F1 to be spaced apart from each other in the vertical direction DR3. A second plurality of nanosheets NW2 may be disposed on the second active pattern F2. The second plurality of nanosheets NW2 may be spaced apart from the first plurality of nanosheets NW1 in the first horizontal direction DR1. The second plurality of nanosheets NW2 may be disposed at the intersection between the second active pattern F2 and the second gate electrode G2. The second plurality of nanosheets NW2 may include a plurality of nanosheets stacked on the second active pattern F2 to be spaced apart from each other in the vertical direction DR3.

Although FIGS. 2 and 3 show that each of the first and second plurality of nanosheets NW1 and NW2 include three nanosheets stacked to be spaced apart from each other in the vertical direction DR3, this is only for convenience of explanation, and the present disclosure is not limited thereto. In some other embodiments, each of the first and second plurality of nanosheets NW1 and NW2 may include four or more nanosheets stacked to be spaced apart from each other in the vertical direction DR3. For example, each of the first and second plurality of nanosheets NW1 and NW2 may include silicon (Si). However, the present disclosure is not limited thereto. In some other embodiments, each of the first and second plurality of nanosheets NW1 and NW2 may include silicon germanium (SiGe).

The first gate electrode G1 may extend in the second horizontal direction DR2 on the first active pattern F1 and the field insulating layer 105. The first gate electrode G1 may at least partially surround the first plurality of nanosheets NW1. The second gate electrode G2 may extend in the second horizontal direction DR2 on the second active pattern F2 and the field insulating layer 105. The second gate electrode G2 may be spaced apart from the first gate electrode G1 in the first horizontal direction DR1. The second gate electrode G2 may at least partially surround a second plurality of nanosheets NW2.

Each of the first and second gate electrodes G1 and G2 may include, but is not limited to, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. Each of the first and second gate electrodes G1 and G2 may include conductive metal oxide, conductive metal oxynitride or the like, and may include an oxidized form of the aforementioned materials.

A first gate spacer 111 may extend in the second horizontal direction DR2 along both side walls in the first horizontal direction DR1 of the first gate electrode G1, on the upper surface of the uppermost nanosheet of the first plurality of nanosheets NW1 and the field insulating layer 105. The second gate spacer 112 may extend in the second horizontal direction DR2 along both side walls in the first horizontal direction DR1 of the second gate electrode G2, on the upper surface of the uppermost nanosheet of the second plurality of nanosheets NW2, and the field insulating layer 105. Each of the first and second gate spacers 111 and 112 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), or combinations thereof. However, the present disclosure is not limited thereto.

The first source/drain regions SD1 may be disposed on both side walls of the first gate electrode G1 on the first active pattern F1. The first source/drain region SD1 may be in contact with both side walls of the first plurality of nanosheets NW1 in the first horizontal direction DR1. The second source/drain regions SD2 may be disposed on both sides of the second gate electrode G2 on the second active pattern F2. The second source/drain region SD2 may be in contact with both side walls of the second plurality of nanosheets NW2 in the first horizontal direction DR1.

The first gate insulating layer 121 may be disposed between the first gate electrode G1 and the first gate spacer 111. The first gate insulating layer 121 may be disposed between the first gate electrode G1 and the first source/drain region SD1. The first gate insulating layer 121 may be disposed between the first gate electrode G1 and the first active pattern F1. The first gate insulating layer 121 may be disposed between the first gate electrode G1 and the first plurality of nanosheets NW1.

The second gate insulating layer 122 may be disposed between the second gate electrode G2 and the second gate spacer 112. The second gate insulating layer 122 may be disposed between the second gate electrode G2 and the second source/drain region SD2. The second gate insulating layer 122 may be disposed between the second gate electrode G2 and the second active pattern F2. The second gate insulating layer 122 may be disposed between the second gate electrode G2 and the second plurality of nanosheets NW2.

For example, the first gate insulating layer 121 may be in contact with the first source/drain region SD1. Further, the second gate insulating layer 122 may be in contact with the second source/drain region SD2. However, the present disclosure is not limited thereto. In some other embodiments, an internal spacer may be disposed between the first gate insulating layer 121 and the first source/drain region SD1 and/or between the second gate insulating layer 122 and the second source/drain region SD2. In this case, the internal spacer may include, for example, at least one of silicon nitride (SiN), silicon oxynitride (SiON), silicon carbonitride (SiCN), silicon oxycarbonitride (SiOCN), silicon boronitride (SiBN), silicon oxyboronitride (SiOBN), silicon oxycarbide (SiOC), or combinations thereof.

Each of the first and second gate insulating layers 121 and 122 may include at least one of silicon oxide, silicon oxynitride, silicon nitride or a high dielectric constant material having a higher dielectric constant than silicon oxide. The high dielectric constant material may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

The semiconductor device according to some embodiments may include an NC (Negative Capacitance) FET that uses a negative capacitor. For example, each of the first and second gate insulating layers 121 and 122 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be larger than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), or yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, silicon oxide and a metal oxide having a high dielectric constant. The metal oxide included in the paraelectric material film may include, for example, but is not limited to, at least one of hafnium oxide, zirconium oxide, or aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but is not limited to, 0.5 to 10 nm. Since a thickness that exhibits the ferroelectric properties may vary for each ferroelectric material, the thickness of the ferroelectric material film may vary depending on the ferroelectric material.

As an example, each of the first and second gate insulating layers 121 and 122 may include one ferroelectric material film. As another example, each of the first and second gate insulating layers 121 and 122 may include a plurality of ferroelectric material films spaced apart from each other. Each of the first and second gate insulating layers 121 and 122 may have a stacked film structure in which a plurality of ferroelectric material films and a plurality of paraelectric material films are alternately stacked.

The first etching stop layer 140 may be disposed on a side wall of the first gate spacer 111 in the first horizontal direction DR1. The first etching stop layer 140 may be disposed on the side wall of the second gate spacer 112 in the first horizontal direction DR1. Although not shown, the first etching stop layer 140 may be disposed on the upper surface of the field insulating layer 105 in a region in which each of the first and second gate electrodes G1 and G2 is not disposed. Although not shown, the first etching stop layer 140 may be disposed on the side walls of each of the first and second source/drain regions SD1 and SD2 in the second horizontal direction DR2. For example, the first etching stop layer 140 may be formed conformally. The first etching stop layer 140 may include, for example, at least one of aluminum oxide, aluminum nitride, hafnium oxide, zirconium oxide, silicon oxide, silicon nitride, silicon oxynitride, and a low dielectric constant material.

The first capping pattern 131 may extend in the second horizontal direction DR2 on each of the first gate spacer 111, the first gate insulating layer 121, and the first gate electrode G1. The second capping pattern 132 may extend in the second horizontal direction DR2 on each of the second gate spacer 112, the second gate insulating layer 122, and the second gate electrode G2. For example, lower surfaces of each of the first capping pattern 131 and the second capping pattern 132 may be in contact with the first etching stop layer 140. However, the present disclosure is not limited thereto. In some other embodiments, side walls of each of the first capping pattern 131 and the second capping pattern 132 may be in contact with the first etching stop layer 140. Each of the first capping pattern 131 and the second capping pattern 132 may include, for example, at least one of silicon nitride (SiN), silicon oxynitride (SiON), silicon oxide (SiO₂), silicon carbonitride (SiCN), silicon oxycarbonitride (SiOCN), or combinations thereof. However, the present disclosure is not limited thereto.

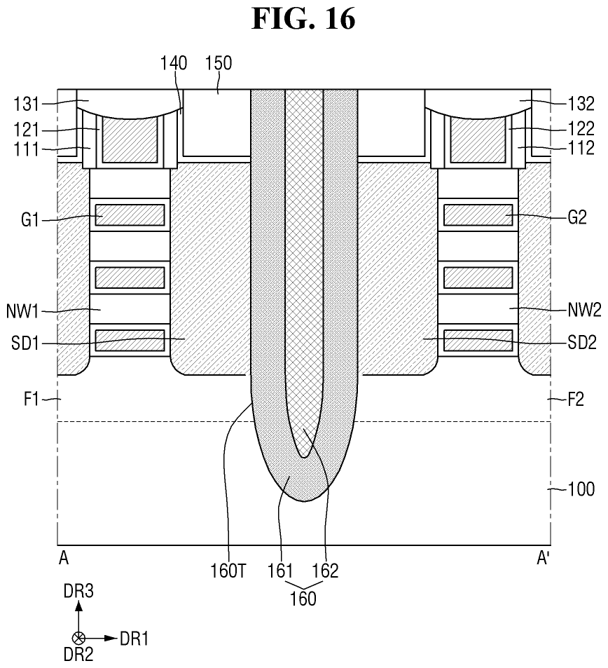

Although not shown in FIGS. 2 and 3, a first interlayer insulating layer (150 of FIG. 16) may be disposed on the first etching stop layer 140. Although not shown in FIGS. 2 and 3, the first interlayer insulating layer (150 of FIG. 16) may at least partially surround side walls of each of the first and second capping patterns 131 and 132 in the region in which each of the first to fourth source/drain contacts CA1, CA2, CA3 and CA4 is not disposed. Although not shown in FIGS. 2 and 3, the first interlayer insulating layer (150 of FIG. 16) may cover or overlap each of the first and second source/drain regions SD1 and SD2 on the field insulating layer 105. For example, the upper surface of the first interlayer insulating layer (150 of FIG. 16) may be formed on the same plane as the upper surfaces of each of the first and second capping patterns 131 and 132.

The first interlayer insulating layer (150 of FIG. 16) may include, for example, at least one of silicon oxide, silicon nitride, silicon oxynitride, and a low dielectric constant material. The low dielectric constant material may include, for example, but is not limited to, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

An active cut trench 160T may extend in the second horizontal direction DR2 between the first gate electrode G1 and the second gate electrode G2. The active cut trench 160T may extend in the second horizontal direction DR2 between the first active pattern F1 and the second active pattern F2. The active cut trench 160T may be formed between the first source/drain region SD1 and the second source/drain region SD2. The active cut trench 160T may separate the first active pattern F1 and the second active pattern F2 in the first horizontal direction DR1.

For example, the active cut trench 160T may extend into the interior of the substrate 100. That is, a bottom surface of the active cut trench 160T may be formed inside the substrate 100. Although FIG. 2 shows that the active cut trench 160T extends to the lower surfaces of each of the first and second source/drain contacts CA1 and CA2 in the region in which each of the first and second source/drain contacts CA1 and CA2 is disposed, the present disclosure is not limited thereto. Although not shown, in the region in which each of the first and second source/drain contacts CA1 and CA2 is not provided, the active cut trench 160T may extend to the upper surface of the first interlayer insulating layer (150 of FIG. 16). That is, at least a part of each of the first and second source/drain contacts CA1 and CA2 may be defined as being disposed inside the active cut trench 160T.

The active cut 160 may be disposed inside the active cut trench 160T. For example, the active cut 160 may extend in the second horizontal direction DR2 between the first gate electrode G1 and the second gate electrode G2. The active cut 160 may extend in the second horizontal direction DR2 between the first active pattern F1 and the second active pattern F2. The active cut 160 may be formed between the first source/drain region SD1 and the second source/drain region SD2. The active cut 160 may separate the first active pattern F1 and the second active pattern F2 in the first horizontal direction DR1.

For example, the active cut 160 may include a first layer 161 and a second layer 162. The first layer 161 may be disposed along the side walls and the bottom surface of the active cut trench 160T. For example, the first layer 161 may be disposed in a liner shape. The first layer 161 may be in contact with each of the substrate 100, the side wall of the first active pattern F1 in the first horizontal direction DR1, and the side wall of the second active pattern F2 in the first horizontal direction DR1. Further, the first layer 161 may be in contact with each of the first source/drain region SD1 and the second source/drain region SD2.

The second layer 162 may be disposed on the first layer 161 inside the active cut trench 160T. The second layer 162 may fill or be in the active cut trench 160T on the first layer 161. For example, the second layer 162 may extend to the upper surface of the first interlayer insulating layer (150 of FIG. 16). For example, the upper surface of the second layer 162 may be formed on the same plane as the upper surface of the first interlayer insulating layer (150 of FIG. 16).

For example, the first layer 161 may include an oxide. The first layer 161 may include, for example, silicon oxide (SiO₂), silicon oxynitride (SiON) or silicon oxycarbonitride (SiOCN). The second layer 162 may include a different material from the first layer 161. The second layer 162 may include a material that has a different etching selectivity from the first layer 161. For example, the second layer 162 may include nitride. The second layer 162 may include, for example, silicon nitride (SiN), silicon carbonitride (SiCN), silicon oxynitride (SiON) or silicon oxycarbonitride (SiOCN).

A first source/drain contact CA1 may be disposed on a first side of the first gate electrode G1 in the first horizontal direction DR1. The first source/drain contact CA1 may extend in the second horizontal direction DR2. The first source/drain contact CA1 may be electrically connected to the first source/drain region SD1 disposed on the first side of the first gate electrode G1 in the first horizontal direction DR1.

A second source/drain contact CA2 may be disposed on a second side of the first gate electrode G1 that is opposite to the first side of the first gate electrode G1 in the first horizontal direction DR1. The second source/drain contact CA2 may be disposed between the first gate electrode G1 and the active cut 160. The second source/drain contact CA2 may extend in the second horizontal direction DR2. The second source/drain contact CA2 may be electrically connected to the first source/drain region SD1 disposed between the first gate electrode G1 and the active cut 160.

For example, at least a part of the second source/drain contact CA2 may overlap the active cut 160 in the vertical direction DR3. For example, at least a part of the second source/drain contact CA2 may overlap the first layer 161 in the vertical direction DR3. For example, at least a part of the lower surface of the second source/drain contact CA2 may be in contact with the upper surface of the first layer 161. For example, a first side wall of the second source/drain contact CA2 in the first horizontal direction DR1 may be in contact with the first etching stop layer 140. Further, a second side wall of the second source/drain contact CA2 that is opposite to the first side wall of the second source/drain contact CA2 in the first horizontal direction DR1 may be in contact with the second layer 162. For example, the upper surface of the second source/drain contact CA2 may be formed on the same plane as the upper surface of the second layer 162.

A third source/drain contact CA3 may be disposed on the first side of the second gate electrode G2 in the first horizontal direction DR1. The third source/drain contact CA3 may be disposed between the active cut 160 and the second gate electrode G2. The third source/drain contact CA3 may extend in the second horizontal direction DR2. The third source/drain contact CA3 may be electrically connected to the second source/drain region SD2 disposed between the active cut 160 and the second gate electrode G2.

For example, at least a part of the third source/drain contact CA3 may overlap the active cut 160 in the vertical direction DR3. For example, at least a part of the third source/drain contact CA3 may overlap the first layer 161 in the vertical direction DR3. For example, at least a part of the lower surface of the third source/drain contact CA3 may be in contact with the upper surface of the first layer 161. For example, a first side wall of the third source/drain contact CA3 in the first horizontal direction DR1 may be in contact with the second layer 162. Also, a second side wall of the third source/drain contact CA3 that is opposite to the first side wall of the third source/drain contact CA3 in the first horizontal direction DR1 may be in contact with the first etching stop layer 140. For example, the upper surface of the third source/drain contact CA3 may be formed on the same plane as the upper surface of the second layer 162.

A fourth source/drain contact CA4 is disposed on the second side of the second gate electrode G2, which is opposite to the first side of the second gate electrode G2 in the first horizontal direction DR1. The fourth source/drain contact CA4 may extend in the second horizontal direction DR2. The fourth source/drain contact CA4 may be electrically connected to the second source/drain region SD2 disposed on the second side of the second gate electrode G2 in the first horizontal direction DR1.

For example, the second source/drain contact CA2 may include a contact barrier layer CA2_1 and a contact filling layer CA2_2. The contact barrier layer CA2_1 may form side walls and a bottom surface of the second source/drain contact CA2. The contact barrier layer CA2_1 may be disposed in a liner shape. The contact barrier layer CA2_1 may be in contact with the upper surface of the first layer 161. In addition, the contact barrier layer CA2_1 may be in contact with the side wall of the second layer 162 in the first horizontal direction DR1 and the first etching stop layer 140. The contact filling layer CA2_2 may be disposed on the contact barrier layer CA2_1. The contact filling layer CA2_2 may form the interior of the second source/drain contact CA2. For example, each of the first, third, and fourth source/drain contacts CA1, CA3, and CA4 may include a contact barrier layer CA2_1 and a contact filling layer CA2_2, similarly to the second source/drain contact CA2.

Each of the contact barrier layer CA2_1 and the contact filling layer CA2_2 may include a conductive material. The contact barrier layer CA2_1 may include, for example, at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh). The contact filling layer CA2_2 may include, for example, at least one of aluminum (Al), tungsten (W), cobalt (Co), ruthenium (Ru), and molybdenum (Mo).

A silicide layer SL may be disposed between each of the first and second source/drain contacts CA1 and CA2 and the first source/drain region SD1. The silicide layer SL may be disposed along an interface between each of the first and second source/drain contacts CA1 and CA2 and the first source/drain region SD1. Further, the silicide layer SL may be disposed between each of the third and fourth source/drain contacts CA3 and CA4 and the second source/drain region SD2. The silicide layer SL may be disposed along the interface between each of the third and fourth source/drain contacts CA3 and CA4 and the second source/drain region SD2.

For example, at least a part of the silicide layer SL disposed between the second source/drain contact CA2 and the first source/drain region SD1 may be in contact with the first layer 161. Further, at least a part of the silicide layer SL disposed between the third source/drain contact CA3 and the second source/drain region SD2 may be in contact with the first layer 161. The silicide layer SL may include, for example, a metal silicide material.

For example, the gate contact CB may pass or extend through the first capping pattern 131 in the vertical direction DR3 and be connected to the first gate electrode G1. For example, the upper surface of the gate contact CB may be formed on the same plane as the upper surface of the first capping pattern 131, but the present disclosure is not limited thereto. In some other embodiments, the upper surface of the gate contact CB may be formed to be higher than the upper surface of the first capping pattern 131 (e.g., a distance between the upper surface of the gate contact CB and the substrate 100 is greater than a distance between the upper surface of the first capping pattern 131 and the substrate 100). Although the gate contact CB is shown to be formed of a single film in FIG. 3, this is for convenience of explanation, and the present disclosure is not limited thereto. That is, the gate contact CB may be formed of multiple films. The gate contact CB may include a conductive material.

The second etching stop layer 170 may be disposed on the upper surfaces of each of the first to fourth source/drain contacts CA1, CA2, CA3 and CA4, the gate contact CB, the first and second capping patterns 131 and 132, and the first interlayer insulating layer (150 of FIG. 16). Although the second etching stop layer 170 is shown as being formed of a single layer in FIGS. 2 and 3, the present disclosure is not limited thereto. In some other embodiments, the second etching stop layer 170 may be formed of multiple films. The second etching stop layer 170 may include, for example, at least one of aluminum oxide, aluminum nitride, hafnium oxide, zirconium oxide, silicon oxide, silicon nitride, silicon oxynitride, and a low dielectric constant material.

The second interlayer insulating layer 180 may be disposed on the second etching stop layer 170. The second interlayer insulating layer 180 may include, for example, at least one of silicon oxide, silicon nitride, silicon oxynitride, and a low dielectric constant material. A first via V1 may pass or extend through the second interlayer insulating layer 180 and the second etching stop layer 170 in the vertical direction DR3, and may be connected to any one of the first to fourth source/drain contacts CA1, CA2, CA3 and CA4. A second via V2 may pass or extend through the second interlayer insulating layer 180 and the second etching stop layer 170 in the vertical direction DR3, and may be connected to the gate contact CB. Although each of the first via V1 and the second via V2 is shown to be formed of a single film in FIGS. 2 and 3, this is for convenience of explanation, and the present disclosure is not limited thereto. That is, each of the first via V1 and the second via V2 may be formed of multiple films. Each of the first via V1 and the second via V2 may include a conductive material.

The semiconductor device according to some embodiments of the present disclosure may be formed such that a part of the source/drain contact CA2 overlaps the active cut 160 in the vertical direction DR3. Therefore, in the semiconductor device according to some embodiments of the present disclosure, the electrical characteristics of the semiconductor device may be improved by forming the width of the source/drain contact CA2 to be relatively large.

Hereinafter, a method for fabricating the semiconductor device according to some embodiments of the present disclosure will be described with reference to FIGS. 2 to 17.

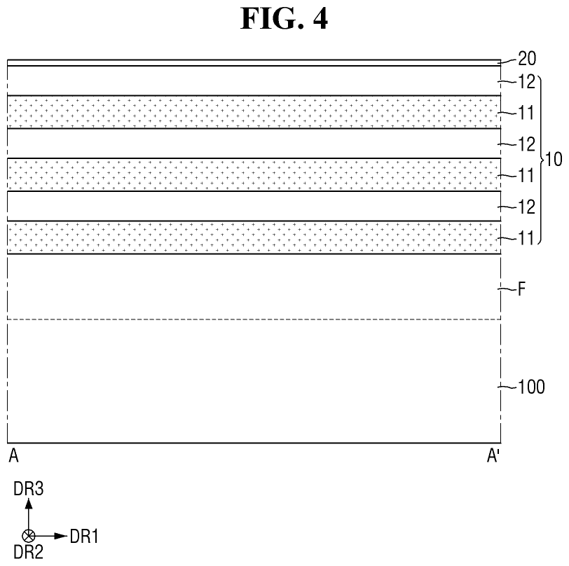

FIGS. 4 to 17 are intermediate step diagrams for explaining the method for fabricating the semiconductor device according to some embodiments of the present disclosure.

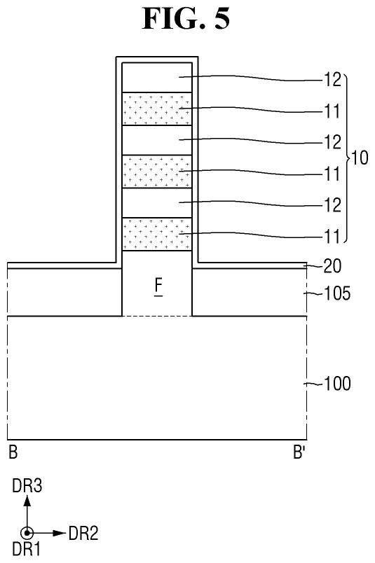

Referring to FIGS. 4 and 5, a stacked structure 10 may be formed on the substrate 100. The stacked structure 10 may include a first semiconductor layer 11 and a second semiconductor layer 12 that are alternately stacked on the substrate 100. For example, the first semiconductor layer 11 may be formed at the bottom of the stacked structure 10, and the second semiconductor layer 12 may be formed at the top of the stacked structure 10. However, the present disclosure is not limited thereto. In some other embodiments, the first semiconductor layer 11 may also be formed at the top of the stacked structure 10. The first semiconductor layer 11 may include, for example, silicon germanium (SiGe). The second semiconductor layer 12 may include, for example, silicon (Si).

A part of the stacked structure 10 may then be etched. A part of the substrate 100 may also be etched, while the stacked structure 10 is being etched. Through such an etching process, an active layer F may be defined in the lower part of the stacked structure 10 on the substrate 100. The active layer F may extend in the first horizontal direction DR1. Subsequently, a field insulating layer 105 may be formed on the substrate 100. The field insulating layer 105 may at least partially surround the side walls of the active layer F. For example, the upper surface of the active layer F may be formed to be higher than the upper surface of the field insulating layer 105. Subsequently, a pad oxide layer 20 may be formed to cover or overlap the upper surface of the field insulating layer 105, the exposed side walls of the active layer F, and the side walls and upper surface of the stacked structure 10. For example, the pad oxide layer 20 may be formed conformally. The pad oxide layer 20 may include, for example, silicon oxide (SiO₂).

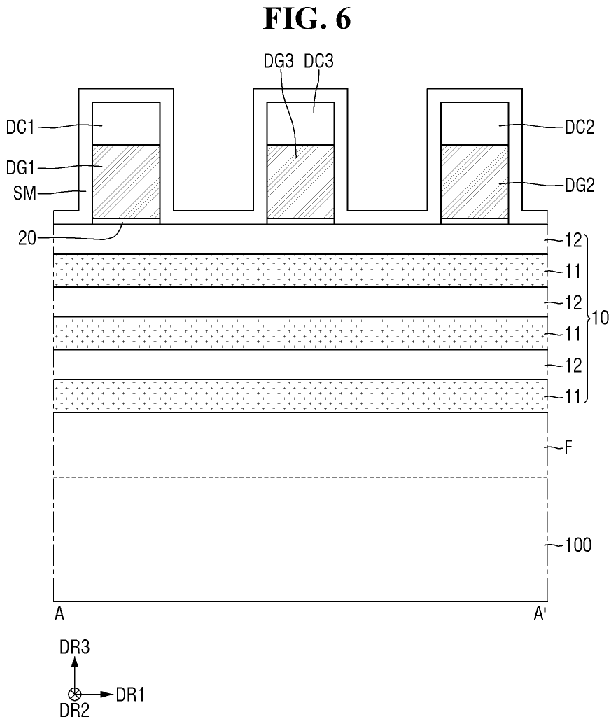

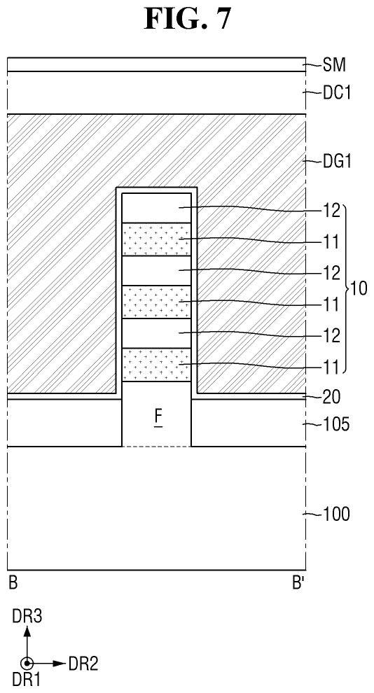

Referring to FIGS. 6 and 7, first to third dummy gates DG1, DG2 and DG3 and the third dummy capping patterns DC1, DC2, and DC3 extending in the second horizontal direction DR2 on the pad oxide layer 20 may be formed on the stacked structure 10 and the field insulating layer 105. For example, a third dummy gate DG3 may be spaced apart from the first dummy gate DG1 in the first horizontal direction DR1. A second dummy gate DG2 may be spaced apart from the third dummy gate DG3 in the first horizontal direction DR1. A first dummy capping pattern DC1 may be disposed on the first dummy gate DG1. A second dummy capping pattern DC2 may be disposed on the second dummy gate DG2. A third dummy capping pattern DC3 may be disposed on the third dummy gate DG3.

While the first to third dummy gates DG1, DG2 and DG3 and the first to third dummy capping patterns DC1, DC2 and DC3 are being formed, the remaining pad oxide layer 20 except for the portions that overlap each of the first to third dummy gates DG1, DG2 and DG3 on the substrate 100 in the vertical direction DR3 may be removed.

Next, a spacer material layer SM may be formed to cover or overlap the side walls of each of the first to third dummy gates DG1, DG2 and DG3, the side walls and upper surfaces of each of the first to third dummy capping patterns DC1, DC2 and DC3, the exposed side walls and upper surface of the stacked structure 10, and the upper surface of the field insulating layer 105. For example, the spacer material layer SM may be formed conformally. The spacer material layer SM may include, for example, at least one of silicon nitride (SiN), silicon oxycarbonitride (SiOCN), silicon boron carbonitride (SiBCN), silicon carbonitride (SiCN), silicon oxynitride (SiON), or combinations thereof.

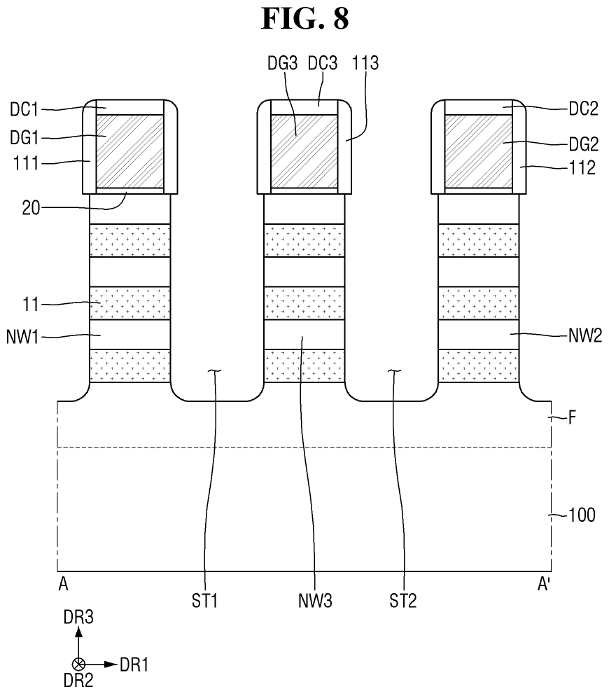

Referring to FIG. 8, the stacked structure (10 of FIG. 6) is etched by using the first to third dummy gates DG1, DG2 and DG3 and the first to third dummy capping patterns DC1, DC2 and DC3 as masks, and first and second source/drain trenches ST1 and ST2 may be formed, respectively. For example, the first source/drain trench ST1 may be formed between the first dummy gate DG1 and the third dummy gate DG3. Further, the second source/drain trench ST2 may be formed between the third dummy gate DG3 and the second dummy gate DG2. For example, each of the first and second source/drain trenches ST1 and ST2 may extend into the interior of the active layer F. While each of the first and second source/drain trenches ST1 and ST2 is being formed, a spacer material layer (SM of FIG. 6) and a part of each of the first to third dummy capping patterns DC1, DC2 and DC3 may be etched.

For example, the spacer material layer (SM of FIG. 6) that remains on the side walls of the first to third dummy capping patterns DC1, DC2 and DC3 and the first to third dummy gates DG1, DG2 and DG3 may be defined as first to third gate spacers 111, 112 and 113. For example, after the first and second source/drain trenches ST1 and ST2 are each formed, each second semiconductor layer (12 of FIG. 6) that remains under each of the first to third dummy gates DG1, DG2, and DG3 on the active layer F may be defined as each of the first to third plurality of nanosheets NW1 and NW2, and NW3.

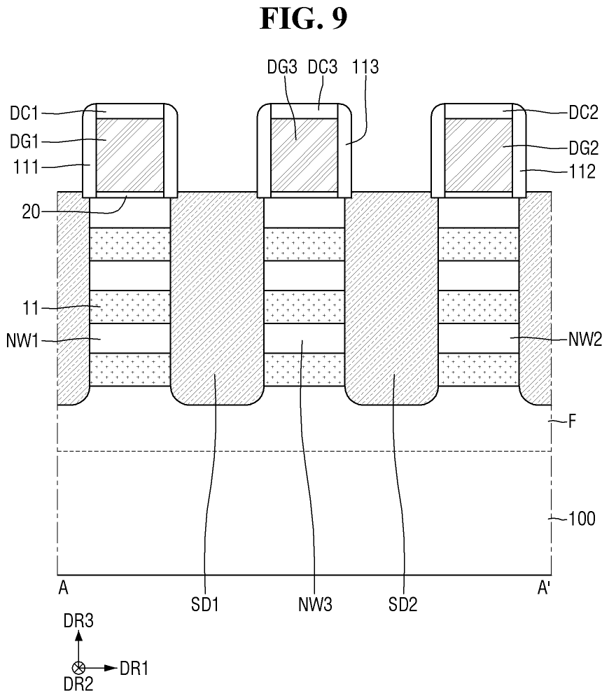

Referring to FIG. 9, a first source/drain region SD1 may be formed inside the first source/drain trench ST1. For example, a first source/drain region SD1 may be formed on the active layer F between the first plurality of nanosheets NW1 and the third plurality of nanosheets NW3. Further, a second source/drain region SD2 may be formed inside the second source/drain trench ST2. For example, a second source/drain region SD2 may be formed on the active layer F between the third plurality of nanosheets NW3 and the second plurality of nanosheets NW2.

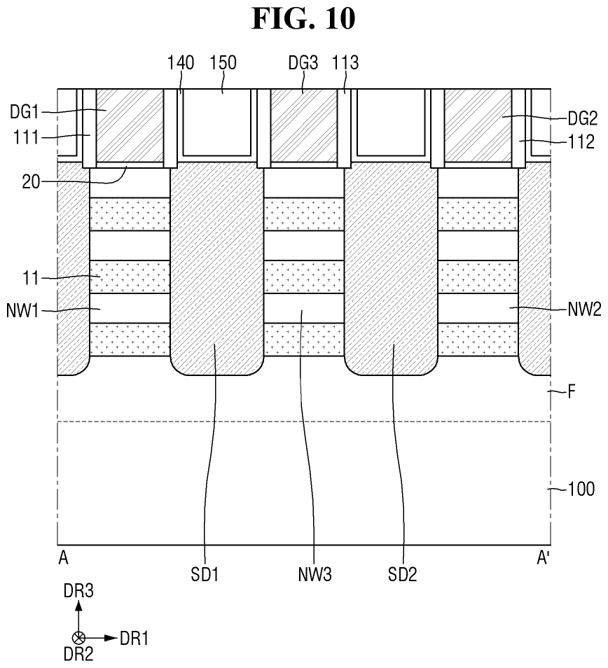

Referring to FIG. 10, the first etching stop layer 140 and the first interlayer insulating layer 150 may be sequentially formed to cover or overlap each of the first and second source/drain regions SD1 and SD2, the first to third gate spacers 111, 112 and 113, and the first to third dummy capping patterns (DC1, DC2 and DC3 of FIG. 9). For example, the first etching stop layer 140 may have a liner shape. Then, the upper surfaces of each of the first to third dummy gates DG1, DG2, and DG3 may be exposed through a planarization process.

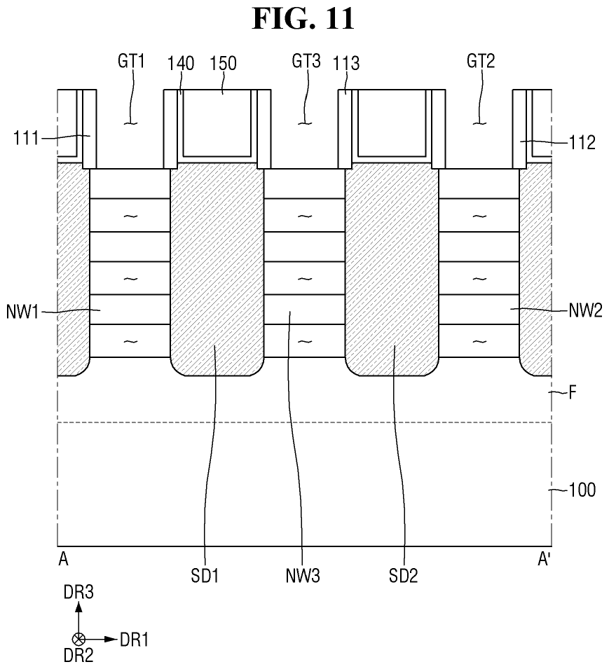

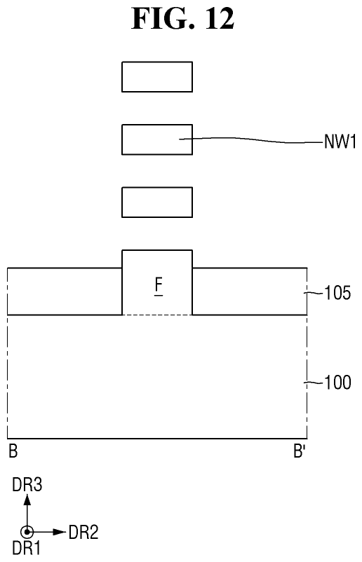

Referring to FIGS. 11 and 12, each of the first to third dummy gates (DG1, DG2, and DG3 of FIG. 10), the pad oxide layer (20 of FIG. 10), and the first semiconductor layer (11 of FIG. 10) may be etched. The portion from which the first dummy gate (DG1 of FIG. 10) is removed may be defined as a first gate trench GT1. The portion from which the second dummy gate (DG2 of FIG. 10) is removed may be defined as a second gate trench GT2. The portion from which the third dummy gate (DG3 of FIG. 10) is removed may be defined as a third gate trench GT3.

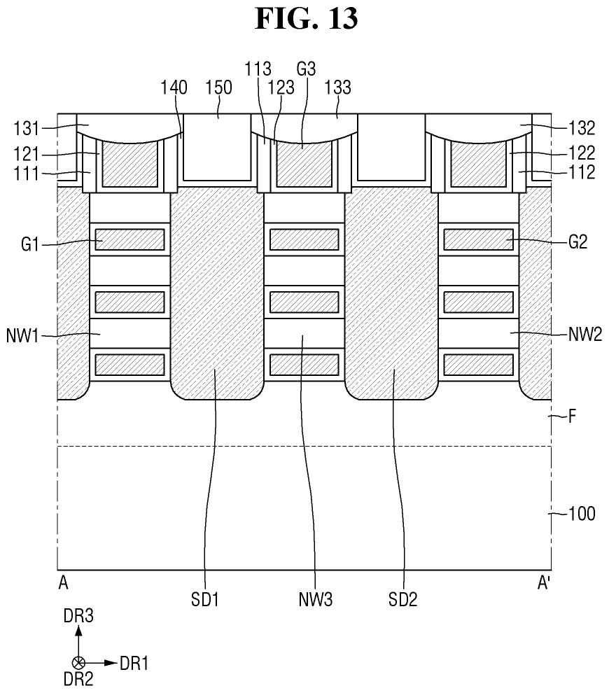

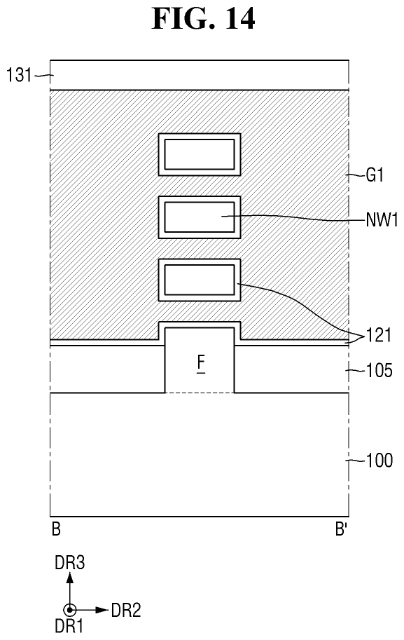

Referring to FIGS. 13 and 14, the first gate insulating layer 121, the first gate electrode G1, and the first capping pattern 131 may be sequentially formed inside the first gate trench (GT1 of FIG. 11). Further, the second gate insulating layer 122, the second gate electrode G2, and the second capping pattern 132 may be sequentially formed inside the second gate trench (GT2 of FIG. 11). Further, the third gate insulating layer 123, the third gate electrode G3, and the third capping pattern 133 may be sequentially formed inside the third gate trench (GT3 of FIG. 11).

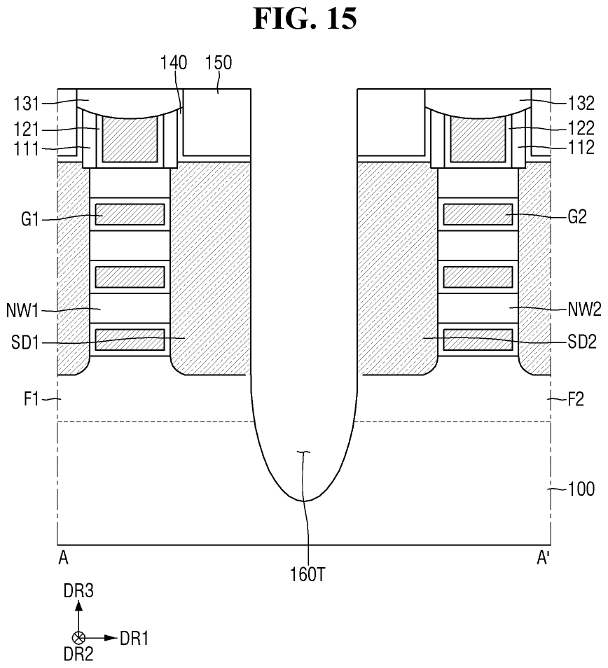

Referring to FIG. 15, an active cut trench 160T may be formed between the first gate electrode G1 and the second gate electrode G2. The active cut trench 160T may be formed by etching each of the third capping pattern (133 of FIG. 13), the third gate spacer (113 of FIG. 13), the third gate insulating layer (123 of FIG. 13), the third gate electrode (G3 of FIG. 13), a part of the first etching stop layer 140, the third plurality of nanosheets (NW3 of FIG. 13), and the active layer (F of FIG. 13). The active cut trench 160T may extend in the second horizontal direction DR2. The active cut trench 160T may extend from the upper surface of the first interlayer insulating layer 150 to the interior of the substrate 100.

After the active cut trench 160T is formed, the active layer (F of FIG. 13) may be separated into a first active pattern F1 and a second active pattern F2. The first active pattern F1 may be formed under the first gate electrode G1 and the first source/drain region SD1. The second active pattern F2 may be formed under the second gate electrode G2 and the second source/drain region SD2. The side walls of each of the first and second source/drain regions SD1 and SD2 in the first horizontal direction DR1, and the side walls of each of the first and second active patterns F1 and F2 in the first horizontal direction DR1 may be exposed through the active cut trench 160T.

Referring to FIG. 16, the first layer 161 and the second layer 162 may be formed inside the active cut trench 160T. The first layer 161 may be formed along the side walls and bottom surface of the active cut trench 160T. For example, the first layer 161 may have a liner shape. The second layer 162 may fill the interior of the active cut trench 160T on the first layer 161.

For example, the first layer 161 may be in contact with each of the side walls of each of the first and second source/drain regions SD1 and SD2 in the first horizontal direction DR1, the side walls of each of the first and second active patterns F1 and F2 in the first horizontal direction DR1, the substrate 100, the first etching stop layer 140, and the first interlayer insulating layer 150. For example, each of the upper surface of the first layer 161 and the upper surface of the second layer 162 may be formed on the same plane as the upper surface of the first interlayer insulating layer 150.

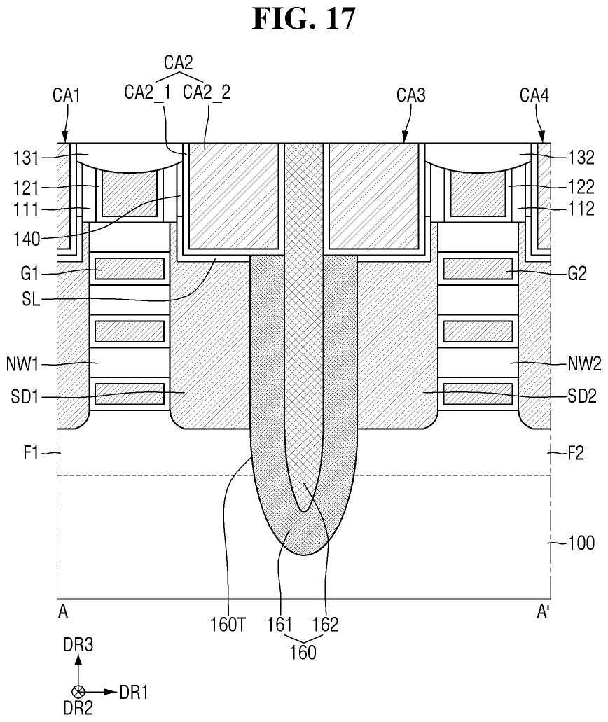

Referring to FIG. 17, first to fourth source/drain contacts CA1, CA2, CA3 and CA4 may be formed inside the first interlayer insulating layer 150, respectively. For example, the first source/drain contact CA1 may be formed on the first source/drain region SD1 on the first side of the first gate electrode G1. The second source/drain contact CA2 may be formed on the first source/drain region SD1 between the second side of the first gate electrode G1 and the second layer 162. The third source/drain contact CA3 may be formed on the second source/drain region SD2 between the second layer 162 and the first side of the second gate electrode G2. The fourth source/drain contact CA4 may be formed on the second source/drain region SD2 on the second side of the second gate electrode G2.

For example, each of the second source/drain contact CA2 and the third source/drain contact CA3 may be formed in a portion in which the first layer 161 is partially etched. That is, each of the second source/drain contact CA2 and the third source/drain contact CA3 may overlap the first layer 161 in the vertical direction DR3. Each of the second source/drain contact CA2 and the third source/drain contact CA3 may be in contact with the upper surface of the first layer 161. For example, side walls of each of the second source/drain contact CA2 and the third source/drain contact CA3 in the first horizontal direction DR1 may be in contact with the second layer 162.

For example, the upper surfaces of each of the first to fourth source/drain contacts CA1, CA2, CA3 and CA4 may be formed on the same plane as the upper surfaces of each of the first and second capping patterns 131 and 132. For example, each of the first to fourth source/drain contacts CA1, CA2, CA3 and CA4 may include a contact barrier layer CA2_1, and a contact filling layer CA2_2 formed on the contact barrier layer CA2_1.

The silicide layer SL may be formed between each of the first and second source/drain contacts CA1 and CA2 and the first source/drain region SD1. Furthermore, the silicide layer SL may be formed between each of the third and fourth source/drain contacts CA3 and CA4 and the second source/drain region SD2. Although not shown, the gate contact (CB of FIG. 3) may pass or extend through the first capping pattern 131 in the vertical direction DR3, and may be connected to the first gate electrode G1.

Referring to FIGS. 2 and 3, the second etching stop layer 170 and the second interlayer insulating layer 180 may be sequentially formed on the upper surfaces of each of the first to fourth source/drain contacts CA1, CA2, CA3 and CA4, the gate contact CB, the first and second capping patterns 131 and 132, and the first interlayer insulating layer (150 of FIG. 16). Subsequently, the first via V1, which passes or extends through the second interlayer insulating layer 180 and the second etching stop layer 170 in the vertical direction DR3 and is connected to one of the first to fourth source/drain contacts CA1, CA2, CA3 and CA4, may be formed. Also, the second via V2, which passes through the second interlayer insulating layer 180 and the second etching stop layer 170 in the vertical direction DR3 and is connected to the gate contact CB, may be formed. By performing such fabricating processes, the semiconductor devices shown in FIGS. 2 and 3 may be fabricated.

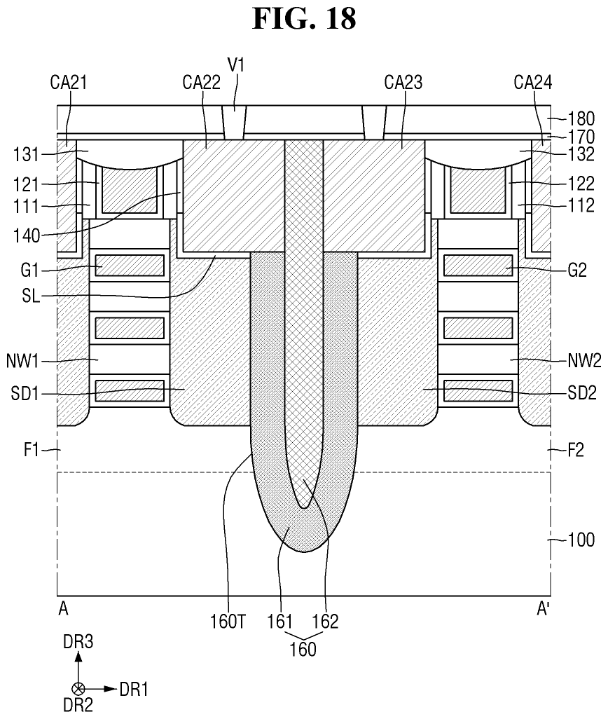

Hereinafter, a semiconductor device according to some other embodiments of the present disclosure will be described with reference to FIG. 18. The explanation will focus on the differences from the semiconductor devices shown in FIGS. 1 to 3.

FIG. 18 is a cross-sectional view for explaining a semiconductor device according to some other embodiments of the present disclosure.

Referring to FIG. 18, in the semiconductor devices according to some other embodiments of the present disclosure, each of the first to fourth source/drain contacts CA21, CA22, CA23, and CA24 may be formed of a single film.

Each of the first to fourth source/drain contacts CA21, CA22, CA23, and CA24 may include a conductive material. For example, each of the first to fourth source/drain contacts CA21, CA22, CA23, and CA24 may include, for example, at least one of tantalum (Ta), titanium (Ti), nickel (Ni), zirconium (Zr), vanadium (V), platinum (Pt), iridium (Ir), rhodium (Rh), aluminum (Al), tungsten (W), cobalt (Co), ruthenium (Ru), and molybdenum (Mo).

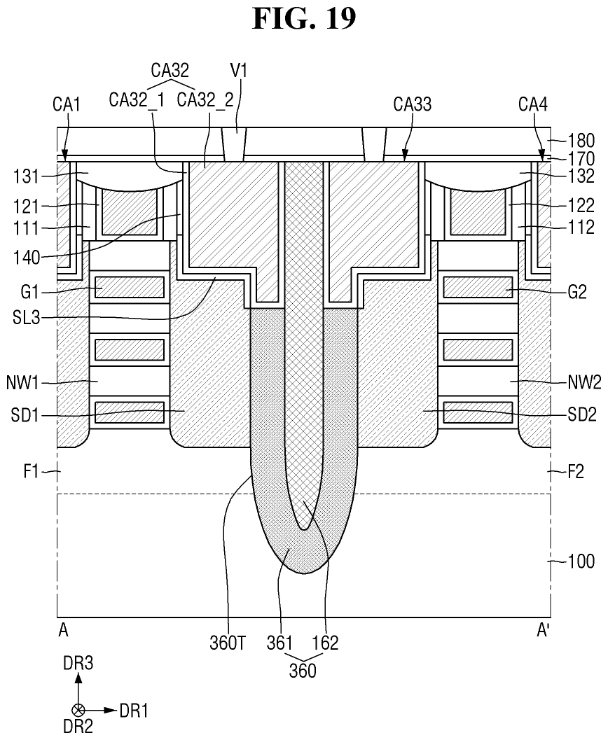

Hereinafter, a semiconductor device according to some other embodiments of the present disclosure will be described with reference to FIG. 19. The explanation will focus on the differences from the semiconductor device shown in FIGS. 1 to 3.

FIG. 19 is a cross-sectional view for explaining a semiconductor device according to some other embodiments of the present disclosure.

Referring to FIG. 19, in the semiconductor device according to some other embodiments of the present disclosure, the lower surfaces of each of the second and third source/drain contacts CA32 and CA33 may have a step.

For example, an active cut 360 may be disposed inside an active cut trench 360T. The active cut 360 may include a first layer 361 disposed along the side wall and bottom surface of the active cut trench 360T, and a second layer 162 disposed on the first layer 361. For example, the second source/drain contact CA32 may include a first lower surface formed on the upper surface of the first source/drain region SD1, and a second lower surface formed on the upper surface of the first layer 361. The first lower surface of the second source/drain contact CA32 may be in contact with the silicide layer SL3 formed on the upper surface of the first source/drain region SD1. A second lower surface of the second source/drain contact CA32 may be in contact with an upper surface of the first layer 361.

For example, the third source/drain contact CA33 may include a first lower surface formed on the upper surface of the second source/drain region SD2, and a second lower surface formed on the upper surface of the first layer 361. The first lower surface of the third source/drain contact CA33 may be in contact with the silicide layer SL3 formed on the upper surface of the second source/drain region SD2. The second lower surface of the third source/drain contact CA33 may be in contact with the upper surface of the first layer 361.

The first lower surface of the second source/drain contact CA32 and the second lower surface of the second source/drain contact CA32 may have a step. For example, the first lower surface of the second source/drain contact CA32 may be formed to be higher than the second lower surface of the second source/drain contact CA32 (e.g., a distance between the first lower surface of the second source/drain contact CA32 and the substrate 100 is greater than a distance between second lower surface of the second source/drain contact CA32 and the substrate 100). Furthermore, the first lower surface of the third source/drain contact CA33 and the second lower surface of the third source/drain contact CA33 may have a step. For example, the first lower surface of the third source/drain contact CA33 may be formed to be higher than the second lower surface of the third source/drain contact CA33.

For example, each of the second and third source/drain contacts CA32 and CA33 may include a contact barrier layer CA32_1 and a contact filling layer CA32_2. The contact barrier layer CA32_1 may form side walls and bottom surfaces of each of the second and third source/drain contacts CA32 and CA33. The contact filling layer CA32_2 may be disposed on the contact barrier layer CA32_1. The contact filling layer CA32_2 may form an interior of each of the second and third source/drain contacts CA32 and CA33.

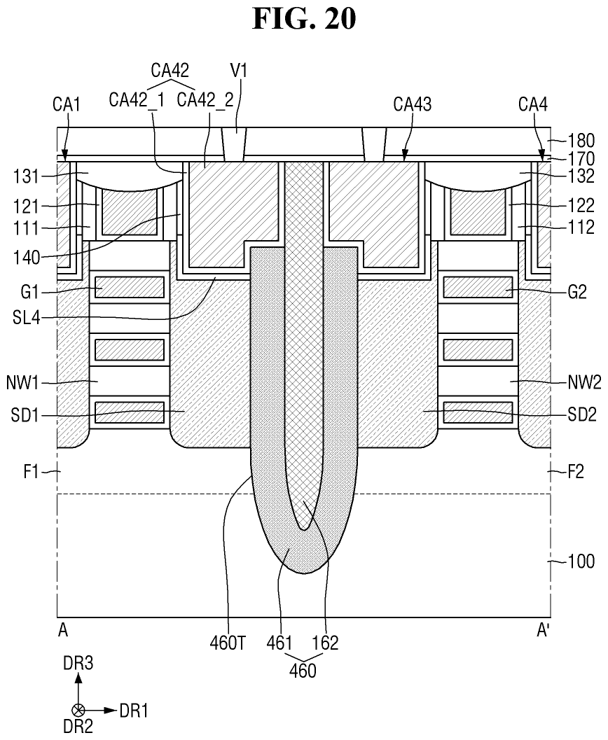

Hereinafter, a semiconductor device according to some other embodiments of the present disclosure will be described with reference to FIG. 20. The explanation will focus on the differences from the semiconductor device shown in FIGS. 1 to 3.

FIG. 20 is a cross-sectional view for explaining a semiconductor device according to some other embodiments of the present disclosure.

Referring to FIG. 20, in the semiconductor device according to some other embodiments of the present disclosure, the lower surfaces of each of the second and third source/drain contacts CA42 and CA43 may have a step.

For example, an active cut 460 may be disposed inside an active cut trench 460T. The active cut 460 may include a first layer 461 disposed along the side wall and bottom surface of the active cut trench 460T, and a second layer 162 disposed on the first layer 461. For example, the second source/drain contact CA42 may include a first lower surface formed on the upper surface of the first source/drain region SD1, and a second lower surface formed on the upper surface of the first layer 461. The first lower surface of the second source/drain contact CA42 may be in contact with the silicide layer SL4 formed on the upper surface of the first source/drain region SD1. The second lower surface of the second source/drain contact CA42 may be in contact with an upper surface of the first layer 461.

For example, the third source/drain contact CA43 may include a first lower surface formed on the upper surface of the second source/drain region SD2, and a second lower surface formed on the upper surface of the first layer 461. The first lower surface of the third source/drain contact CA43 may be in contact with the silicide layer SL4 formed on the upper surface of the second source/drain region SD2. The second lower surface of the third source/drain contact CA43 may be in contact with the upper surface of the first layer 461.

The first lower surface of the second source/drain contact CA42 and the second lower surface of the second source/drain contact CA42 may have a step. For example, the first lower surface of the second source/drain contact CA42 may be formed to be lower than the second lower surface of the second source/drain contact CA42. Further, the first lower surface of the third source/drain contact CA43 and the second lower surface of the third source/drain contact CA43 may have a step. For example, the first lower surface of the third source/drain contact CA43 may be formed to be lower than the second lower surface of the third source/drain contact CA43.

For example, each of the second and third source/drain contacts CA42 and CA43 may include a contact barrier layer CA42_1 and a contact filling layer CA42_2. The contact barrier layer CA42_1 may form side walls and bottom surfaces of each of the second and third source/drain contacts CA42 and CA43. The contact filling layer CA42_2 may be disposed on the contact barrier layer CA42_1. The contact filling layer CA42_2 may form an interior of each of the second and third source/drain contacts CA42 and CA43.

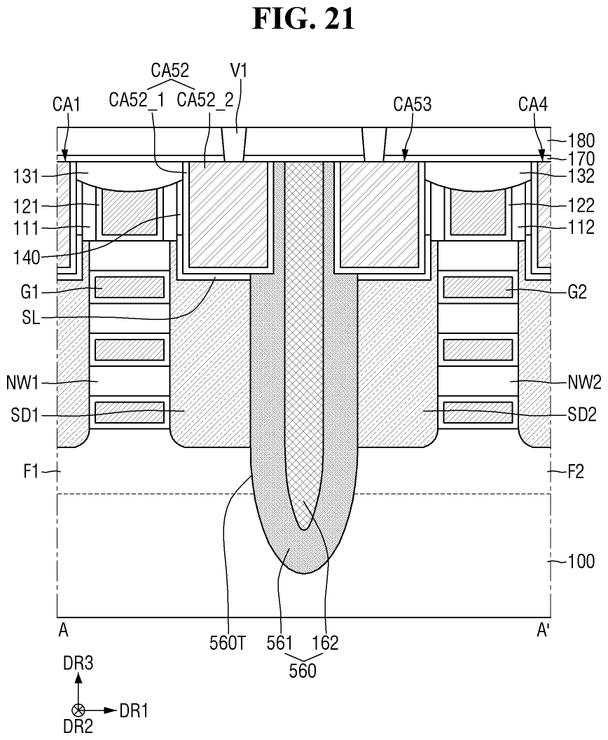

Hereinafter, a semiconductor device according to some other embodiments of the present disclosure will be described with reference to FIG. 21. The explanation will focus on the differences from the semiconductor device shown in FIGS. 1 to 3.

FIG. 21 is a cross-sectional view for explaining a semiconductor device according to some other embodiments of the present disclosure.

Referring to FIG. 21, in the semiconductor device according to some other embodiments of the present disclosure, at least a part of the first layer 561 may be disposed between each of the second and third source/drain contacts CA52 and CA53 and the second layer 162.

For example, an active cut 560 may be disposed inside an active cut trench 560T. The active cut 560 may include a first layer 561 disposed along the side wall and bottom surface of the active cut trench 560T, and a second layer 162 disposed on the first layer 561. For example, a side wall of the second source/drain contact CA52 in the first horizontal direction DR1 may be spaced apart from the second layer 162 in the first horizontal direction DR1. The first layer 561 may be disposed between the side wall of the second source/drain contact CA52 in the first horizontal direction DR1 and the second layer 162. Further, the side wall of the third source/drain contact CA53 in the first horizontal direction DR1 may be spaced apart from the second layer 162 in the first horizontal direction DR1. The first layer 561 may be disposed between the side wall of the third source/drain contact CA53 in the first horizontal direction DR1 and the second layer 162.

For example, each of the second and third source/drain contacts CA52 and CA53 may include a contact barrier layer CA52_1 and a contact filling layer CA52_2. The contact barrier layer CA52_1 may form side walls and bottom surfaces of each of the second and third source/drain contacts CA52 and CA53. The contact filling layer CA52_2 may be disposed on the contact barrier layer CA52_1. The contact filling layer CA52_2 may form an interior of each of the second and third source/drain contacts CA52 and CA53.

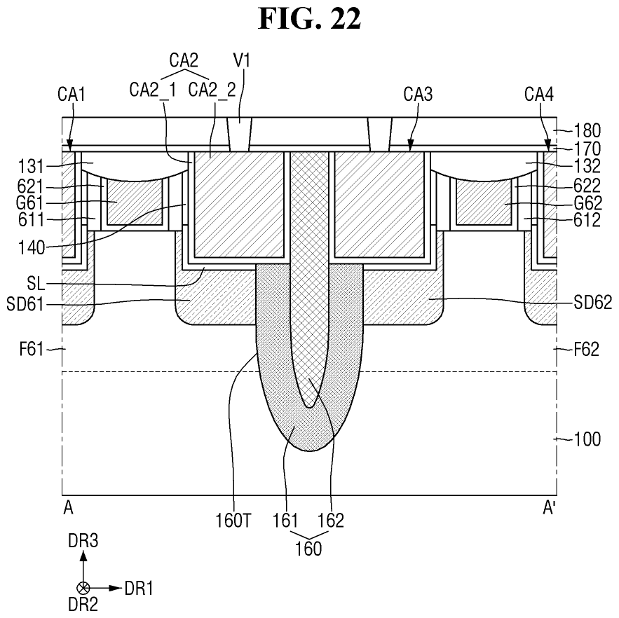

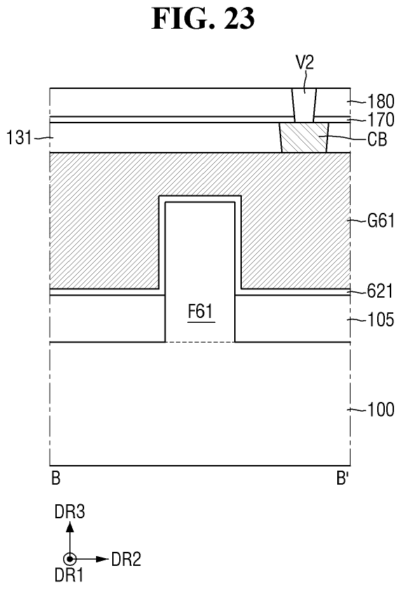

Hereinafter, a semiconductor device according to some other embodiments of the present disclosure will be described with reference to FIGS. 22 and 23. The explanation will focus on the differences from the semiconductor device shown in FIGS. 1 to 3.

FIGS. 22 and 23 are cross-sectional views for explaining a semiconductor device according to some other embodiments of the present disclosure.

Referring to FIGS. 22 and 23, the semiconductor device according to some other embodiments of the present disclosure may include a fin type transistor (FinFET). For example, the semiconductor device according to some other embodiments of the present disclosure may include a substrate 100, first and second active patterns F61 and F62, a field insulating layer 105, first and second gate electrodes G61 and G62, first and second gate spacers 611 and 612, first and second gate insulating layers 621 and 622, first and second capping patterns 131 and 132, first and second source/drain regions SD61 and SD62, a first etching stop layer 140, an active cut 160, first to fourth source/drain contacts CA1, CA2, CA3 and CA4, a silicide layer SL, a gate contact CB, a second etching stop layer 170, a second interlayer insulating layer 180, and first and second vias V1 and V2. Hereinafter, description of the configurations described in FIGS. 1 to 3 will be omitted.

Each of the first active pattern F61 and the second active pattern F62 may extend in the first horizontal direction DR1 on the substrate 100. The second active pattern F62 may be spaced apart from the first active pattern F61 in the first horizontal direction DR1. The first gate electrode G61 may extend in the second horizontal direction DR2 on the first active pattern F61 and the field insulating layer 105. The second gate electrode G62 may extend in the second horizontal direction DR2 on the second active pattern F62 and the field insulating layer 105. The first gate spacer 611 may extend in the second horizontal direction DR2 along both side walls of the first gate electrode G61 on the first active pattern F61. The second gate spacer 612 may extend in the second horizontal direction DR2 along both side walls of the second gate electrode G62 on the second active pattern F62.

A first gate insulating layer 621 may be disposed between the first gate electrode G61 and the first active pattern F61. The first gate insulating layer 621 may be disposed between the first gate electrode G61 and the first gate spacer 611. A second gate insulating layer 622 may be disposed between the second gate electrode G62 and the second active pattern F62. The second gate insulating layer 622 may be disposed between the second gate electrode G62 and the second gate spacer 612. A first source/drain region SD61 may be disposed on both sides of the first gate electrode G61 in the first horizontal direction DR1 on the first active pattern F61. A second source/drain region SD62 may be disposed on both sides of the second gate electrode G62 in the first horizontal direction DR1 on the second active pattern F62.

The active cut trench 160T may separate the first active pattern F61 and the second active pattern F62. The active cut 160 may extend in the second horizontal direction DR2 inside the active cut trench 160T. For example, the active cut 160 may include a first layer 161 and a second layer 162. The first layer 161 may be disposed along the side walls and bottom surface of the active cut trench 160T. The second layer 162 may fill or be in the interior of the active cut trench 160T on the first layer 161.

Although the embodiments of the present disclosure have been described above with reference to the accompanying drawings, the present disclosure is not limited to the above embodiments, and may be fabricated in various forms. Those skilled in the art will appreciate that the present disclosure may be embodied in other specific forms without changing the technical spirit or features of the present disclosure. Accordingly, the above-described embodiments should be understood in all respects as illustrative and not restrictive.

What is claimed is:

1. A semiconductor device comprising:
a substrate;
first and second active patterns that are on the substrate and extend in a first horizontal direction, wherein the second active pattern is spaced apart from the first active pattern in the first horizontal direction;
a first gate electrode that is on the first active pattern and extends in a second horizontal direction that is different from the first horizontal direction;
a second gate electrode that is on the second active pattern and extends in the second horizontal direction, wherein the second gate electrode is spaced apart from the first gate electrode in the first horizontal direction;
an active cut trench that extends in the second horizontal direction and is between the first gate electrode and the second gate electrode, wherein the active cut trench separates the first and second active patterns;
an active cut comprising a first layer and a second layer on the first layer, wherein the first layer is on a side wall and a bottom surface of the active cut trench;
a first source/drain region that is between the first gate electrode and the active cut and is on the first active pattern; and
a first source/drain contact that is on and electrically connected to the first source/drain region, wherein at least a part of the first source/drain contact overlaps the first layer in a vertical direction.

2. The semiconductor device of claim 1, wherein the first source/drain region contacts the first layer.

3. The semiconductor device of claim 1, wherein at least a part of a lower surface of the first source/drain contact contacts the first layer.

4. The semiconductor device of claim 1, further comprising a silicide layer that is between the first source/drain region and the first source/drain contact, wherein at least a part of the silicide layer contacts the first layer.

5. The semiconductor device of claim 1, wherein an upper surface of the second layer and an upper surface of the first source/drain contact are coplanar.

6. The semiconductor device of claim 1, further comprising:
a second source/drain region that is between the active cut and is on the second gate electrode on the second active pattern; and
a second source/drain contact that is on and is electrically connected to the second source/drain region between the active cut and the second gate electrode, wherein at least a part of the second source/drain contact overlaps the first layer in the vertical direction.

7. The semiconductor device of claim 1, wherein the first layer and the second layer comprise different materials from each other.

8. The semiconductor device of claim 1, wherein a side wall of the first source/drain contact contacts the second layer.

9. The semiconductor device of claim 1, wherein at least a part of the first layer is between a side wall of the first source/drain contact and the second layer.

10. The semiconductor device of claim 1, wherein the first source/drain contact comprises:
a contact barrier layer that defines a side wall and a bottom surface of the first source/drain contact, and
a contact filling layer on the contact barrier layer.

11. The semiconductor device of claim 1, wherein the first source/drain contact comprises:
a first lower surface that is on an upper surface of the first source/drain region and spaced apart from the substrate by a first distance in the vertical direction, and
a second lower surface that is on an upper surface of the first layer and spaced apart from the substrate by a second distance in the vertical direction, and
wherein the first distance is greater than the second distance.

12. The semiconductor device of claim 1, further comprising:
a first plurality of nanosheets that are on the first active pattern and spaced apart from each other in the vertical direction, wherein the first gate electrode at least partially surrounds the first plurality of nanosheets; and
a second plurality of nanosheets that are on the second active pattern and are spaced apart from each other in the vertical direction, wherein the second gate electrode at least partially surrounds the second plurality of nanosheets.

13. A semiconductor device comprising:
a substrate;
a first active pattern that is on the substrate and extends in a first horizontal direction on the substrate;
a gate electrode that is on the first active pattern and extends in a second horizontal direction that is different from the first horizontal direction;
an active cut that is spaced apart from the gate electrode in the first horizontal direction, wherein the active cut extends in the second horizontal direction, wherein the active cut contacts a side wall of the first active pattern, and wherein the active cut comprises a first layer that defines a side wall and a bottom surface of the active cut and a second layer on the first layer;
a source/drain region that is between the gate electrode and the active cut and is on the first active pattern, wherein the source/drain region contacts the first layer; and
a source/drain contact that is on and is electrically connected to the source/drain region, wherein at least a part of a lower surface of the source/drain contact contacts an upper surface of the first layer, and wherein an upper surface of the source/drain contact and an upper surface of the second layer are coplanar.

14. The semiconductor device of claim 13, further comprising:
first and second gate spacers that are respectively on first and second side walls of the gate electrode; and
an etching stop layer on a side wall of one of the first and second gate spacers, wherein the etching stop layer contacts the source/drain contact.

15. The semiconductor device of claim 13, further comprising a second active pattern that is on the substrate and extends in the first horizontal direction, wherein the second active pattern is spaced apart from the first active pattern in the first horizontal direction, and wherein the active cut separates the first and second active patterns.

16. The semiconductor device of claim 13, further comprising a silicide layer between the source/drain region and the source/drain contact, wherein at least a part of the silicide layer contacts the first layer.

17. The semiconductor device of claim 13, wherein the second layer contacts side walls of the source/drain contact.

18. The semiconductor device of claim 13, wherein the source/drain contact comprises a single film.

19. The semiconductor device of claim 13, wherein the source/drain contact comprises:
a first lower surface that is on an upper surface of the source/drain region and spaced apart from the substrate by a first distance in a vertical direction, and
a second lower surface that is on the upper surface of the first layer and spaced apart from the substrate by a second distance in the vertical direction, and
wherein the first distance is less than the second distance.

20. A semiconductor device comprising:
a substrate;
first and second active patterns that are on the substrate and extend in a first horizontal direction, wherein the second active pattern is spaced apart from the first active pattern in the first horizontal direction;
a first plurality of nanosheets that are on the first active pattern and spaced apart from each other in a vertical direction;
a second plurality of nanosheets that are on the second active pattern and spaced apart from each other in the vertical direction;
a first gate electrode that is on the first active pattern and extends in a second horizontal direction that is different from the first horizontal direction, wherein the first gate electrode at least partially surrounds the first plurality of nanosheets;
a second gate electrode that is on the second active pattern and extends in the second horizontal direction, wherein the second gate electrode is spaced apart from the first gate electrode in the first horizontal direction, and wherein the second gate electrode at least partially surrounds the second plurality of nanosheets;
an active cut trench that extends in the second horizontal direction and is between the first gate electrode and the second gate electrode, wherein the active cut trench separates the first and second active patterns;
an active cut comprising a first layer that is on a side wall and a bottom surface of the active cut trench, wherein the active cut comprises a second layer that is on the first layer, wherein the first layer contacts side walls of each of the first and second active patterns, and wherein the first layer and the second layer comprise different materials from each other;
a first source/drain region that is between the first gate electrode and the active cut and is on the first active pattern, wherein the first source/drain region contacts the first layer;
a second source/drain region that is between the active cut and the second gate electrode and is on the second active pattern, wherein the second source/drain region contacts the first layer;
a first source/drain contact that is on and electrically connected to the first source/drain region, wherein at least a part of a lower surface of the first source/drain contact contacts the first layer, and wherein a side wall of the first source/drain contact contacts the second layer; and
a second source/drain contact disposed that is on and electrically connected to the second source/drain region, wherein at least a part of a lower surface of the second source/drain contact contacts the first layer, and wherein a side wall of the second source/drain contact contacts the second layer.
